(19) United States
(12) Patent Application Publication
(10) Pub. No.: US 2024/0339424 A1
(43) Pub. Date: Oct. 10, 2024

(54) MICROBUMP STRUCTURE WITH ENCLOSED JOINT WINDOW

(71) Applicant: Taiwan Semiconductor Manufacturing Co., Ltd., Hsinchu (TW)

(72) Inventors: Wei-Yu Chen, Taipei (TW); Chao-Wei Chiu, Hsinchu (TW); Hsin Liang Chen, New Taipei (TW); Hao-Jan Pei, Hsinchu (TW); Hsiu-Jen Lin, Zhubei (TW); Ching-Hua Hsieh, Hsinchu (TW)

(21) Appl. No.: 18/230,793

(22) Filed: Aug. 7, 2023

Related U.S. Application Data
(60) Provisional application No. 63/494,127, filed on Apr. 4, 2023.

(51) Int. Cl. H01L 23/00

(52) U.S. Cl. CPC H01L 24/13; H01L 24/11; H01L 2224/0401; H01L 2924/01322

(57) ABSTRACT

Embodiments provide a device structure and method of forming a device structure including an infill structure to capture solder materials within confines of openings of the infill structure. Metal pillars of one device can penetrate through a non-conductive film and contact solder regions of another device. A separate underfill is not needed.

### PRIORITY CLAIM AND CROSS-REFERENCE

This application claims the benefit of U.S. Provisional Application No. 63/494,127, filed on Apr. 4, 2023, which application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-10 illustrate intermediate stages in the formation of a package component having infill structures and an non-conductive film, in accordance with some embodiments.

FIGS. 11-18 illustrate intermediate stages in the formation of a package having metal pillars of a package component surrounded by a non-conductive film interfacing with solder regions which are surrounded by infill structures of another package component, in accordance with some embodiments.

FIGS. 19-20 illustrate another configuration of a package having metal pillars of a package component surrounded by a non-conductive film interfacing with solder regions which are surrounded by infill structures of another package component, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In system-on-integrated-circuit (SOIC) devices, integrated circuit devices (which may also be referred to as dies or chips) are attached together into a single system device package. Such SOIC devices be formed by bonding, for example, a die to a wafer in a chip-on-wafer bonding process and then later singulating the wafer to form an SOIC device. One way of performing such a bonding is by forming solder connectors that extend between two metal connectors-one on the die and one on the wafer. As the solder connectors get smaller in size and closer together to achieve greater connection density to match device density, there is a greater risk of connector failure. One common failure, for example, is connector bridging or connector collapse. When the solder is reflowed to bond the two structures together, the solder may squeeze laterally between the two structures and bridge to an adjacent connector, causing device failure or unreliability, or the solder can collapse and fail to make any connection. These issues can be caused by having too much or too little solder, by device warpage, by improper alignment, or other reasons.

Embodiments mitigate the problems of connector bridging or connector collapse by confining or enclosing the solder to a particular joint window. The joint window encourages the solder to stay within the lateral extents of the metal connector that it is attached to. Further, embodiments use processes to form the solder which result in more uniform solder structures. The bonding techniques also provide a mechanism for the metal connectors to penetrate the solder prior to reflow, so that the likelihood of a good bond is dramatically increased. Also, a compressible film is provided over the solder to in effect extend the solder window to the metal connectors being bonded to the solder and to help reduce oxidation at the solder joint. In some embodiments, the solder can flow back into the compressible film to surround the metal connectors to provide an enlarged joint.

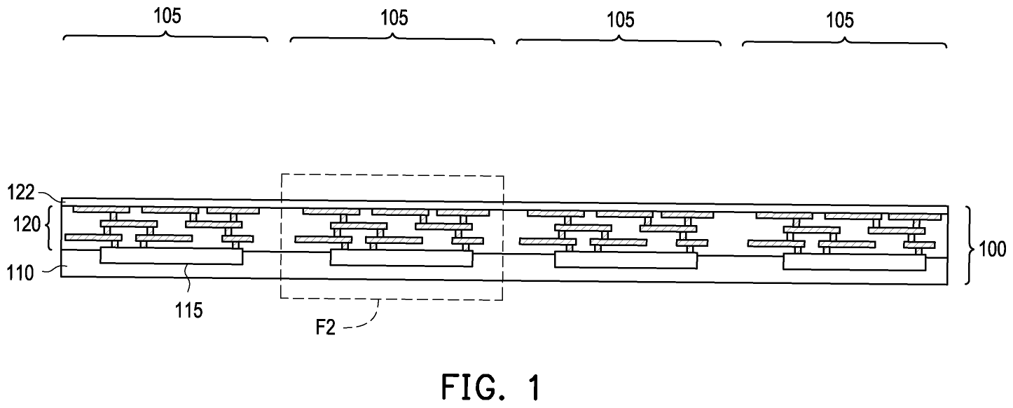

FIG. 1 is a cross-sectional view of a wafer 100 having die regions 105 defined within. In a subsequent process, the die regions 105 may be singulated into multiple integrated circuit dies. The types of dies formed in each of the die regions 105 are not limited. For example, the die regions 105 may be singulated into a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof.

The formation of the integrated circuit dies in each of the die regions 105 may be done according to applicable manufacturing processes to form integrated circuits. For example, the die formed in the die region 105 includes a semiconductor substrate 110, such as silicon, doped or undoped, or an active layer of a semiconductor-on-insulator (SOI) substrate. The semiconductor substrate 110 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 110 has an active surface (e.g., the surface facing upwards in FIG. 1), sometimes called a front side, and an inactive surface (e.g., the surface facing downwards in FIG. 1), sometimes called a back side.

Devices are disposed at the active surface of the semiconductor substrate 110 in a device region 115. The device region 115 may include active devices (e.g., transistors, diodes, etc.), capacitors, resistors, etc. For example, the device region 115 may include transistors that include gate structures and source/drain regions, where the gate structures are on channel regions, and the source/drain regions are adjacent the channel regions.

An interconnect 120 is disposed over the active surface of the semiconductor substrate 110. The interconnect 120 includes one or more dielectric layers, such as an inter-layer dielectric (ILD) or inter-metal dielectric (IMD), with one or more metallization patterns disposed therein. Conductive vias can be used to connect the device region 115 to the metallization patterns and connect metallization patterns to one another. The dielectric layers may be formed of materials such as Phospho-Silicate Glass (PSG), Boro-Silicate Glass (BSG), Boron-Doped Phospho-Silicate Glass (BPSG), undoped Silicate Glass (USG), or the like, which may be formed by a deposition process such as chemical vapor deposition (CVD), atomic layer deposition (ALD), or the like. Conductive vias can extend through the dielectric layers to electrically and physically couple contacts of the devices in the device region 115. In some embodiments, the dielectric layers may be low-k dielectric layers. The metallization patterns and vias may be formed in the dielectric layers 64 by a damascene process, such as a single damascene process, a dual damascene process, or the like. The metallization patterns and conductive vias may be formed of a suitable conductive material, such as copper, tungsten, aluminum, silver, gold, a combination thereof, or the like.

One or more passivation layer(s) 122 are disposed on the interconnect structure 120. The passivation layer(s) 122 may be formed of one or more suitable dielectric materials such as silicon oxynitride, silicon nitride, low-k dielectrics such as carbon doped oxides, extremely low-k dielectrics such as porous carbon doped silicon oxide, a polymer such as polyimide, solder resist, polybenzoxazole (PBO), a benzocyclobutene (BCB) based polymer, molding compound, the like, or a combination thereof. The passivation layer(s) 122 may be formed by chemical vapor deposition (CVD), spin coating, lamination, the like, or a combination thereof. In some embodiments, the passivation layer(s) 122 include a silicon oxynitride layer or a silicon nitride layer.

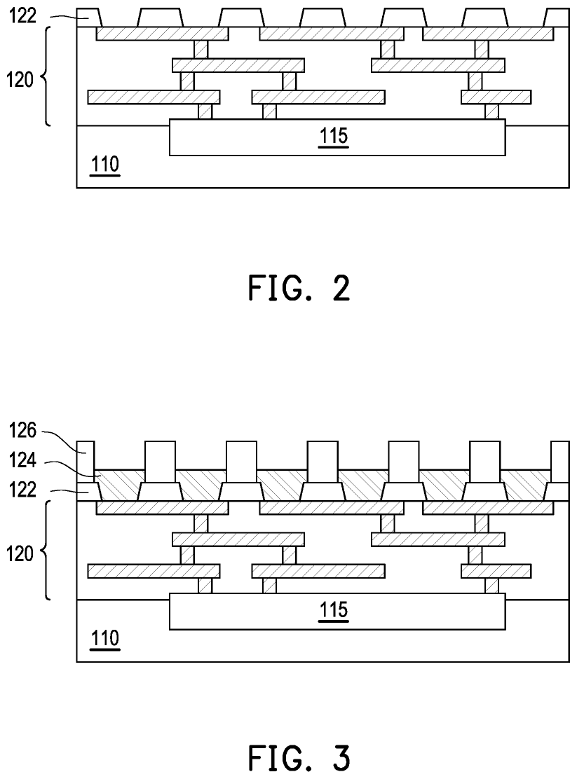

FIGS. 2 through 9A and 9B are magnified views of the dashed box F2 in FIG. 1 and illustrate processes of forming connectors on the die regions 105, in accordance with embodiments.

In FIG. 2, openings are formed in the passivation layer(s) 122. The passivation layer(s) 122 may be patterned using acceptable photolithography and etching techniques to form the openings, the openings exposing conductive elements electrically coupled to the interconnect 120. For example, a photomask may be formed over the passivation layer(s) 122 by spin coat or another deposition, exposed to a light pattern, and developed to form a pattern therein. The passivation layer(s) 122 may be patterned by transferring the photomask pattern to the passivation layer(s) 122 by an etching technique to form the openings. Then, the photomask may be removed using any acceptable technique, such as an ashing technique.

In FIG. 3, under bump metallurgies (UBMs) 124 are formed in the openings of the passivation layer(s) 122. In accordance with some embodiments of the present disclosure, the UBMs 124 are formed to be in contact with a metallization of the interconnect structure 120. In accordance with alternative embodiments, additional conductive lines and possibly dielectric layers are formed over the interconnect 120 underlying the UBMs 124. For example, there may be metal pads formed over the interconnect structure 120 and the UBMs 124 may be formed over the metal pads.

As an example of forming the UBMs 124, a seed layer (not specifically illustrated) may be deposited over the passivation layer(s) 122. The seed layer may include a multi-layer structure and may include a first layer of a titanium layer, a titanium nitride layer, a tantalum layer, a tantalum nitride layer, or the like, and a second upper layer of copper or a copper alloy. The seed layer may be a single layer, which may be a copper layer, for example. The seed layer may be formed using Physical Vapor Deposition (PVD), Plasma Enhanced CVD (PECVD), atomic layer deposition, etc., while other applicable methods may also be used. The seed layer is a conformal layer that extends into openings of the passivation layer(s) 122 and contacts the metal feature exposed by the openings. A plating mask 126 is formed over the seed layer and patterned to form openings corresponding to the UBMs 124. The plating mask 126 may be formed of a photoresist by spin on and patterned using acceptable photolithography techniques. The openings in the plating mask 126 expose portions of the seed layer in the openings of the passivation layer(s) 122. The patterning of plating mask 126 may include a light-exposure process and a development process.

A plating process(es) is performed to form the UBMs 124. UBMs 124 may include one or a plurality of non-solder metal layers. For example, UBMs 124 may include a copper-containing layer including copper or a copper alloy. UBMs 124 may also include metal cap layer (illustrated as being part of the UBMs 124, as applicable) over the copper-containing layer. The metal cap layer may be a nickel-containing layer, a palladium-containing layer, a gold layer, and/or the like, or a composite layer comprising the aforementioned layers. The metal cap layer, if used, may be formed by plating on the copper-containing layer.

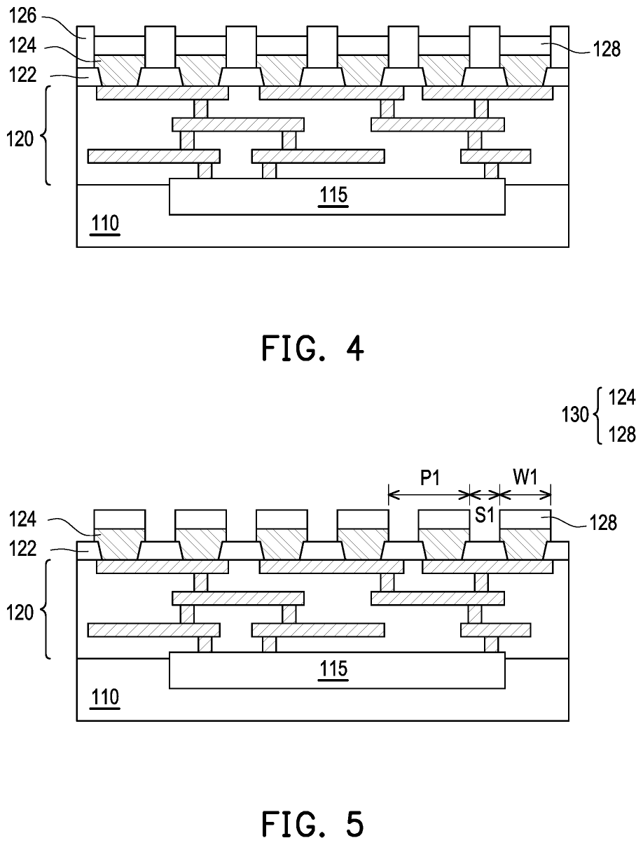

In FIG. 4, the plating mask 126 is left in place for the formation of the solder regions 128 on top of the UBMs 124, which may be formed by a plating process. Solder regions 128 may be formed of a eutectic material, such as a Sn—Ag alloy, a Sn—Ag—Cu alloy, or the like, and may be lead-free or lead-containing. Alternatively, the solder regions 128 may be formed by a printing process depositing solder paste on the UBMs 124. In such embodiments, the plating mask 126 can serve as a printing mask and solder paste can be wiped across the plating mask 126 in the openings. The solder paste may then be reflowed to form the solder regions 128.

In FIG. 5, after plating the solder regions 128, the plating mask 126 is removed by a stripping process, such as by an ashing process. Removing the plating mask 126 uncovers and exposes portions of the seed layer between the UBMs 124. Next, the exposed portions of seed layer that were previously covered by the plating mask 126 are removed through etching. The portions of seed layer covered by the UBMs 124 remain un-removed. Throughout the description, the remaining portions of the seed layer are considered as integral to and part of the UBMs 124. The resulting connector structure 130 includes the UBMs 124 and solder regions 128.

Embodiments may utilize a narrow pitch set or a wider pitch set. For the purposes of this disclosure, a narrow pitch set is considered to be where the pitch P1 between adjacent ones of the UBMs is between about 5 μm and about 15 μm. Wider pitch sets may include a pitch P1 between about 20 μm and 200 μm. In the narrow pitch set, the width W1 of each of the connector structures may be between about 0.5 μm and about 8 μm, and the spacing Si between the connector structures may be between about 3 μm and about 9 μm.

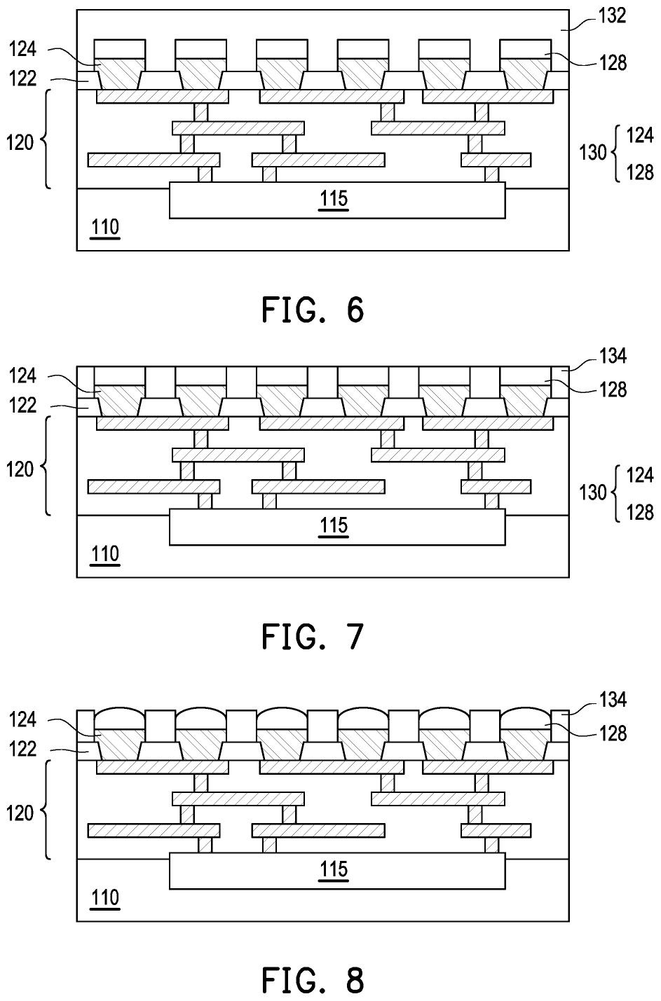

In FIG. 6, an infill film 132 is deposited over and between the connector structures 132 The infill film 132 may be any suitable insulating film, such as a polymer such as polyimide, solder resist, polybenzoxazole (PBO), a benzocyclobutene (BCB) based polymer, or molding compound. The infill film 132 may be deposited using any suitable process, such as by CVD, spin coating, lamination, the like, or a combination thereof. The infill film 132 may have a Young's Modulus between 2.8 and 3.5 GPa for a BCB film or polyimide film or between about 5 and 5.4 for a molding compound film. The infill film 132 may have a coefficient of thermal expansion between about 20 and 70 ppm/° C.

In FIG. 7, a planarization process is performed to level the upper surfaces of the infill film 132 with the upper surfaces of the solder regions 128 of the connector structures 130, to form infill structures 134. The planarization process may include a mechanical grinding or polishing process or may include a chemical mechanical polishing (CMP) process. As a result of the planarization process, the upper surfaces of the structure of FIG. 7, including the solder regions 128 and the infill structures 134 has good planarity, within process variations.

The infill structures 134 provide a constrained joint window which prevents the solder regions 128 from expanding beyond the infill structures 134 or reduces an amount of solder expanding beyond the infill structures 134. The infill structure 134 allow the joint window to be expanded wider because the risk of joint bridging is reduced or eliminated. In some embodiments, the width of the joint window may be between about 20% and 60% of the joint pitch, such as between bout 40% and 60% of the joint pitch.

In FIG. 8, an optional reflow process may be performed on the solder regions 128. The reflow process may be performed to melt the solder regions 128 and cause the solder regions 128 to form a domed shape. In reflowing the solder regions 128, the upper surface of the solder regions 128 may pull away at the edges and recess below the upper surface of the infill structures 134 and the domed or rounded shape of the solder regions 128 may extend above the upper surface of the infill structures 134. As such, the sidewalls of the infill structures 134 may be exposed from the solder regions 128 at their upper most portions. The optional reflow process may be a convection reflow process, laser reflow process, or the like.

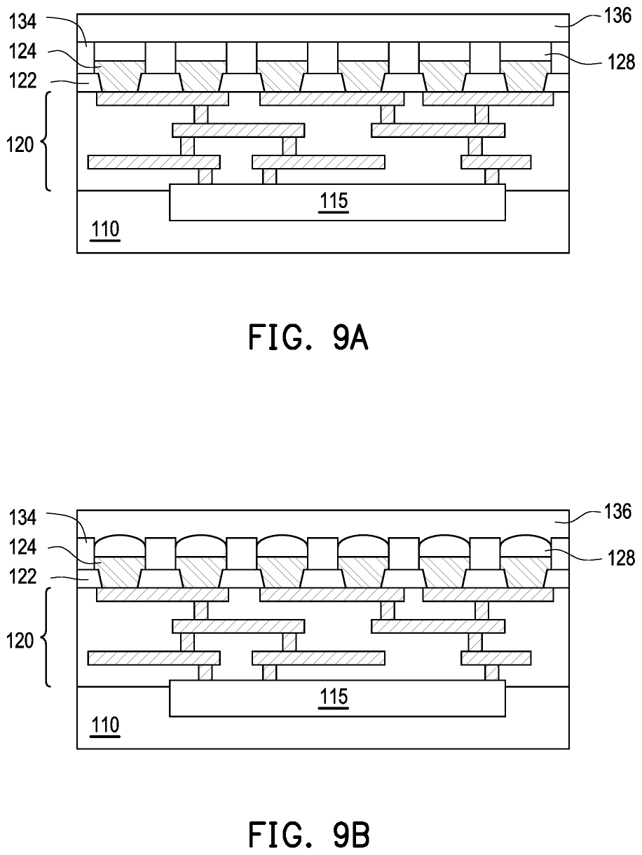

In FIGS. 9A and 9B, a non-conductive film (NCF) 136 is deposited over the infill structures 134 and over the solder regions 128. In FIG. 9A the NCF 136 is deposited over the structure of FIG. 7, and in FIG. 9B the NCF 136 is deposited over the structure of FIG. 8. The NCF 136 is used to aid in coupling the solder regions 128 by containing flux to assist in solder reflow and de-oxidation. The NCF 136 can also serve to extend the joint window to a contact being bonded to the solder regions 128, as will be explained below. The NCF 136 may be any suitable material composition. In some embodiments, the NCF 136 may be a coating adhesive with flux or an epoxy resin with filler and flux. The NCF 136 may be a compressible film and may be formed by any suitable process, such as by lamination, spin-on, or the like, and may be formed to a thickness between about 5 μm and about 10 μm. In FIG. 9B, the NCF 136 may interface with the solder regions 128 and an inner sidewall of the infill structures 134. The NCF 136 may have a Young's Modulus between about 6 and 10 GPa, and may have a coefficient of thermal expansion between about 25 and 40 ppm/° C.

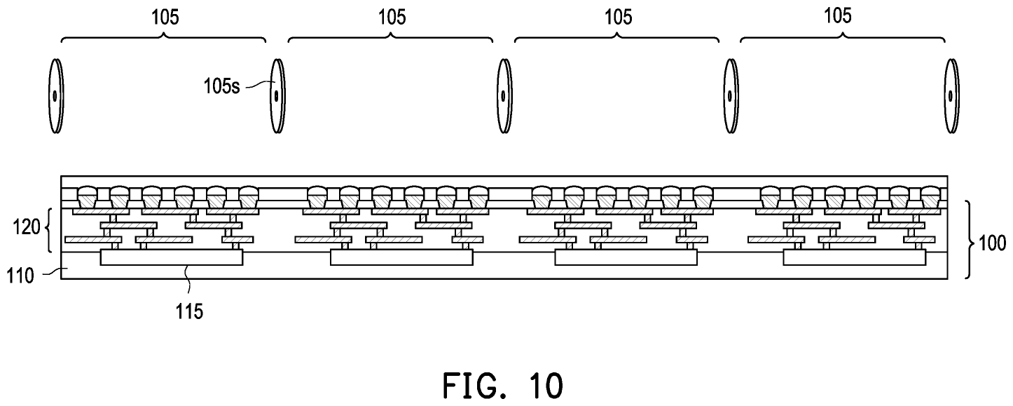

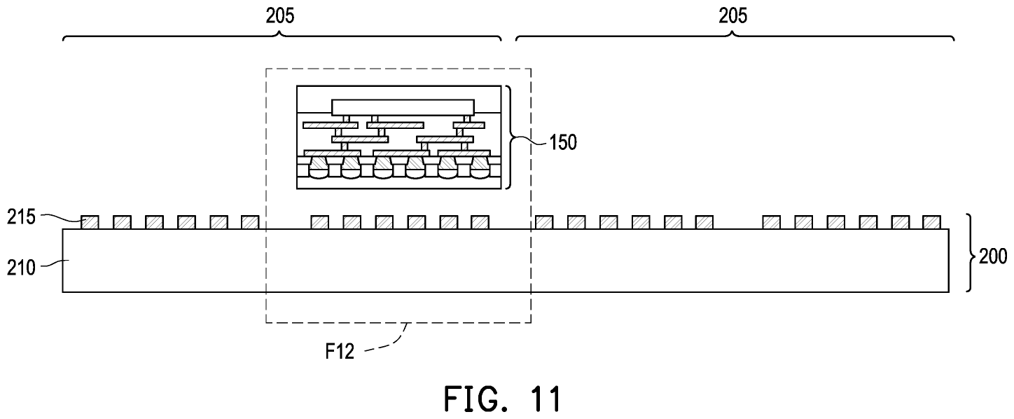

In FIG. 10 the wafer 100 is singulated in a singulation process 105s. The singulation process may include a die-saw process, an etching process, a laser cutting process, the like, or combinations thereof. The singulation is performed along scribe lines between the die regions 105. Package components 150 (see FIG. 11), which may be device dies, package substrate, interposers, packages, or the like are thus separated from each other to form discrete package components 150.

In FIG. 11, a package component 200 is provided, which may be an interposer, a package substrate, a package, a device die, a printed circuit board, or the like. The package component 200 includes a substrate 210 and metal pillars 215 protruding from the substrate 210. The metal pillars 215 are set at the same pitch as the connector structures 130 of the package components 150. The metal pillars 215 may protrude between about 4 μm and 12 μm from the substrate 210, in some embodiments. The metal pillars 215 may have a width which is between about 0.2 μm and 1 μm smaller than the width W1, in accordance with some embodiments. In other embodiments, the width of the metal pillars 215 may be larger than the width W1. The metal pillars 215 may be coupled to conductive features embedded in the substrate 210, which are not specifically illustrated, but may include an interconnect structure, similar to the interconnect structure 120, a device region, similar to the device region 115, or other conductive features. In some embodiments, the substrate 210 may be a wafer having multiple device regions 205 disposed therein, which can be singulated in a subsequent singulation process. The substrate 210 may include any of the candidate materials as those discussed above for the substrate 110.

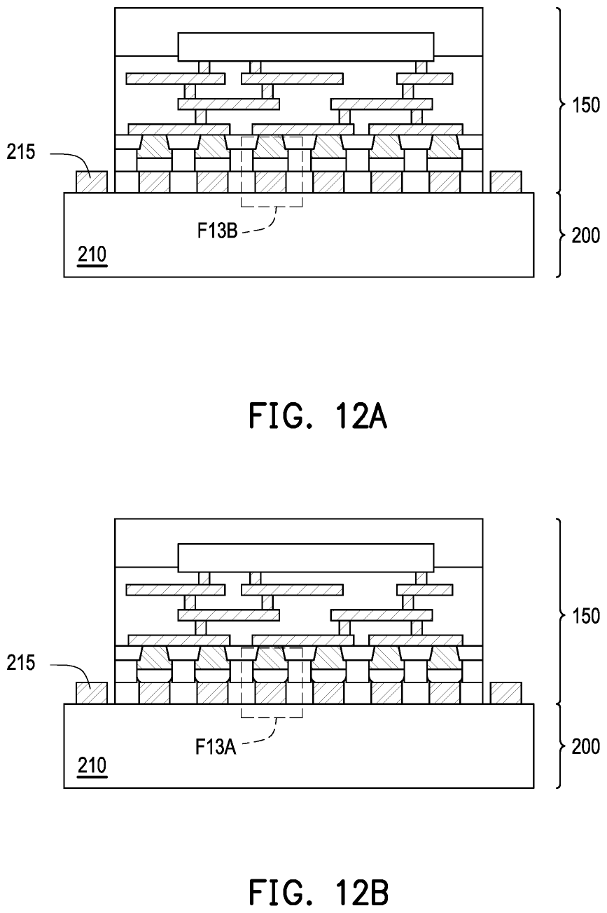

Sill referring to FIG. 11, the package component 150 is aligned to selected ones of the metal pillars 215. The alignment may be accomplished by a pick and place process. Although the package component 150 of FIG. 9B is illustrated, it should be understood that the package component 150 of FIG. 9A may instead be used. Although one package component 150 is illustrated, it should be understood that additional package components, including additional package components 150 may be used. The dashed box F12 is provided in an enlarged view in FIG. 12.

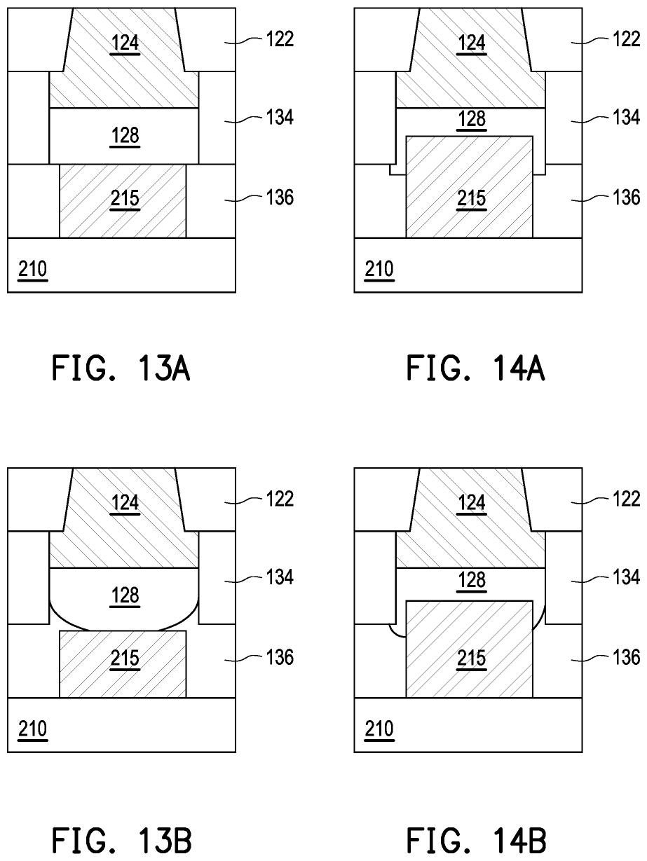

In FIGS. 12A and 12B, the package component 150 is brought to the package component 200 and pressed into the package component 200. FIG. 12A illustrates the package component 150 of FIG. 9A and FIG. 12B illustrates the package component 150 of FIG. 9B. Upon pressing the package component 150 to the package component 200, the metal pillars 215 of the package component 200 penetrate through the NCF 136 to contact the solder regions 128 of the package component 150. As the metal pillars 215 of the package component 200 penetrate the NCF 136, the NCF 136 surrounds the metal pillars 215, contacting the sidewalls of the metal pillars 215. The dashed boxes F13A and F13B are provided in an enlarged view in FIGS. 13A and 13B, respectively.

In FIGS. 13A and 13B, enlarged views of the connector structure 130 are provided. FIG. 13A represents embodiments which the reflow process of FIG. 8 is not performed, i.e., resulting from using the package component 150 of FIG. 9A. FIG. 13B represents embodiments which the reflow process of FIG. 8 is performed, i.e., resulting from the using the package component 150 of FIG. 9B. As seen in FIGS. 13A and 13B, the metal pillars 215 are brought to the surface of the solder regions 128 and are surrounded by the NCF 136. Because the NCF 136 may be a compressible film, when the height of the metal pillars 215 are within about 0-2 μm greater than the thickness of the NCF 136, the NCF 136 may fill the spaces between the metal pillars 215 and may contact the surface of the package component 200.

In FIGS. 14A and 14B, if the height of the metal pillars 215 is greater than the thickness of the NCF 136, for example, between about 2 μm and about 8 μm greater than the thickness of the NCF 136, the metal pillars 215 may stab or penetrate into the solder regions 128 by a penetration distance. The penetration distance may correspond to the height of the metal pillars 215 minus the thickness of the NCF 136 minus the compressibility distance of the NCF 136, for example, between about 0 μm and about 6 μm. As illustrated in FIGS. 14A and 14B, upon stabbing the metal pillars 215 into the solder regions 128, in some embodiments, the solder regions 128 may squeeze toward the package component 200 and expand slightly beyond the lateral extents of the opening in the infill structures 134 which correspond to the solder regions 128.

After aligning and pressing the package component 150, the bonding process can continue by performing a thermocompression bonding (TCB) process. The combination of the package component 150 and package component 200 may be heated to a peak temperature of at least 217° C. for a time between 15 seconds and 21 seconds to reflow the solder of the solder regions 128, while at the same time applying pressure to the package component 150 toward the package component 200 of about 0.5 to 1.5 MPa. The combination of the package component 150 and the package component 200 may be placed in a pressure oven and baked at a temperature between 150° C. and 200° C. at a pressure between 1 atm and 6 atm, for a time between 1 hour and 4 hours. Because the NCF 136 may contain flux, the NCF 136 can aide in reflow of the material of the solder regions 128.

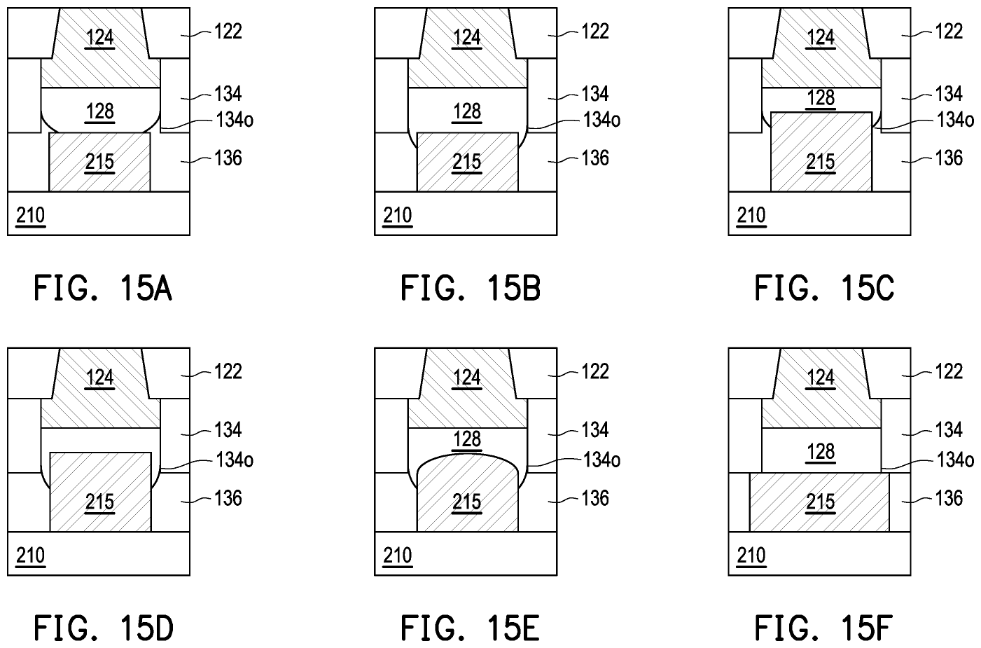

Referring to FIGS. 15A-15F, different enlarged results of the joints between the package component 150 and the package component 200 following the TCB process and baking process are illustrated, in accordance with various embodiments. The embodiments illustrated in FIGS. 15A-15F may result from the package component 150 of FIG. 12A or the package component 150 of FIG. 12B. During the TCB process and the baking process, as illustrated in FIG. 15A, the NCF 136 can move into the opening 1340 in the infill structure 134, and the reflowed solder regions 128 can contact an upper surface of the metal pillars 215. In FIG. 15B, the solder regions 128 have moved into the NCF 136 and surround and contact sidewalls of the metal pillars 215 in addition to contacting the upper surface of the metal pillars 215. In FIG. 15C, the metal pillars 215 stabbed into the solder regions 128, such as illustrated in FIGS. 14A and 14B, and the NCF 136 can move into the opening 1340 in the infill structure 134, and the reflowed solder regions 128 can surround and contact sidewalls of the metal pillars 215 in addition to contacting the upper surface of the metal pillars 215. In FIG. 15D, the metal pillars 215 stabbed into the solder regions 128, such as illustrated in FIGS. 14A and 14B, and the solder regions 128 can move into the NCF 136, and the reflowed solder regions 128 can surround and contact sidewalls of the metal pillars 215 in addition to contacting the upper surface of the metal pillars 215.

In FIG. 15E, the upper surfaces of the metal pillars 215 are curved, in accordance with some embodiments. When the metal pillars 215 are curved, they can more easily stab into the solder regions 128 for forming a better bond. Further, the solder regions 128 can readily move into the NCF 136 to surround more of and contact sidewalls of the metal pillars 215 in addition to contacting the upper curved surface of the metal pillars 215.

In FIGS. 15B, 15D, and 15E, the solder regions 128 that move into the NCF 136 can expand horizontally or laterally beyond the lateral extents of the opening 1340 in the infill structures 134 by a distance between 0 μm and 2 μm. However, due to the infill structures 134 and the NCF 136, the solder regions 128 cannot expand to a neighboring joint, which may be, for example, between 5 μm and 15 μm away when a narrow pitch is used.

In FIG. 15F, the metal pillars 215 are wider than the openings 1340 of the infill structures 134. In such embodiments, the metal pillars 215 stop on the surface of the infill structures 134. Following the TCB process and baking process, the solder regions 128 are completely contained within the openings 1340 and interface with the upper surface of the metal pillars 215. A portion of the upper surface of the metal pillars 215 remains free from the material of the solder regions 128. These portions, however, have an interface with the material of the infill structures 134.

It should be appreciated that each of the joints resulting from the TCB process and baking process illustrated in FIGS. 15A through 15F may be found in the attachment of one of the package components 150 to the package component 200, in any combination. For example, two or more of the joints illustrated in FIGS. 15A through 15F may be between the package component 150 and the package component 250. Further, the features of the joints illustrated in FIGS. 15A through 15F can be combined as appropriate to form a joint which is a composite of two or more of the joints illustrated in FIGS. 15A through 15F.

After the bonding, the NCF 136 can support the joints and a separate underfill is not needed.

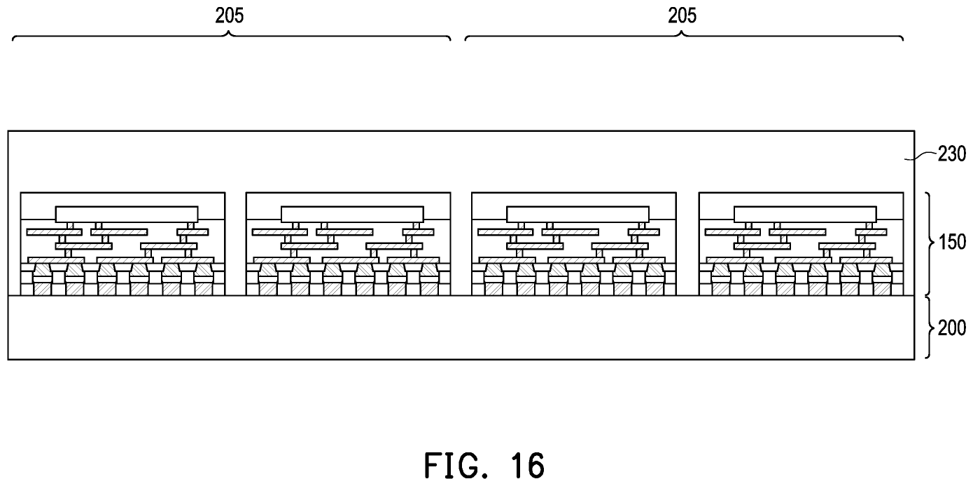

FIG. 16 illustrates multiple package components 150 attached to the package component 200 using the TCB process and baking process to attach the package components 150 to the package component 200. It should be appreciated that the multiple package components 150 may have different configurations and functions, i.e., may be different package types, in some embodiments, while in other embodiments, each of the multiple package components 150 may be the same type.

Following attaching the package components 150 to the package component 200, an encapsulant 230 may be deposited over and between the package components 150. The encapsulant 230 may be a molding compound, a dielectric material, a polyimide, a polymer, and so forth, or combinations thereof. The encapsulant 230 may be deposited by any suitable process, such as by spin-on, CVD, flowable CVD, lamination, compression, and so forth.

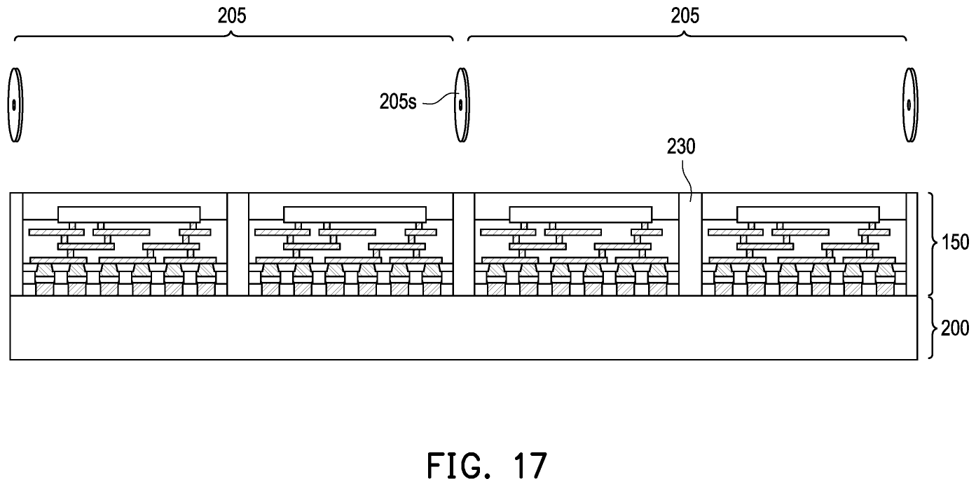

In FIG. 17, the encapsulant 230 may be planarized, such as by a chemical mechanical planarization (CMP) process so that the upper surfaces of the package components 150 and the upper surface of the encapsulant 230 are leveled to each other. In some embodiments, the planarization may be continued to thin the package components 150.

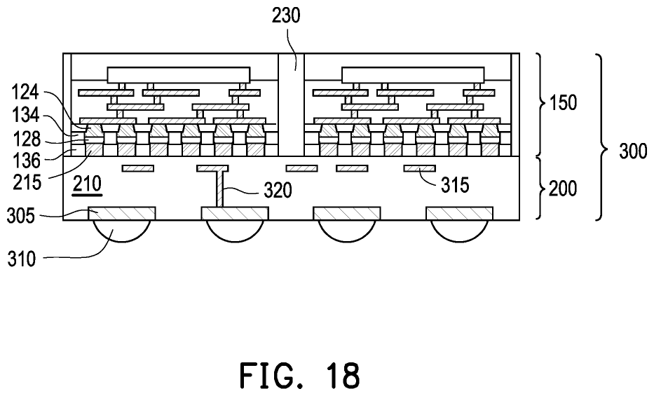

In FIG. 17, the combination of the package components 150 and package component 200 may be singulated using a singulation process 205s so that package regions 205 are separated from each other. The singulation process 205s may include a die-saw process, an etching process, a laser cutting process, the like, or combinations thereof. The singulation process 205s is performed along scribe lines between the package regions 205. Package regions 205 are thus separated from each other to form discrete package components 300 (see FIG. 18).

FIG. 18 illustrates the singulated discrete package components 300. Following the singulation, the discrete package components 300 can be used in another package or in another device structure. In some embodiment, such as illustrated in FIG. 18, before or after singulation, the conductive connectors 310 may be formed on a side of the substrate 210 opposite the package components 150. Forming the conductive connectors 310 may include forming contact pads 305 at the surface of the substrate 210, the contact pads 305 electrically coupled to the metal pillars 215, for example by an interconnect 315 and through vias 320 of the package component 200. The conductive connectors 310 can be formed on the contact pads 305. In some embodiments, the conductive connectors 310 may include optional under bump metallurgies (UBMs) extending through a passivation layer disposed on the substrate 210. The UBMs may be formed of the same material as the contact pads 305. The conductive connectors 310 may include ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 310 may include a conductive material such as solder, copper, aluminum, gold, nickel, silver, palladium, tin, the like, or a combination thereof. The conductive connectors 310 may be formed by sputtering, printing, electro plating, electroless plating, CVD, or the like. In some embodiments, the conductive connectors 310 include a metal pillar and a metal cap layer formed on the top of the metal pillar. The metal cap layer may include nickel, tin, tin-lead, gold, silver, palladium, indium, nickel-palladium-gold, nickel-gold, the like, or a combination thereof and may be formed by a plating process.

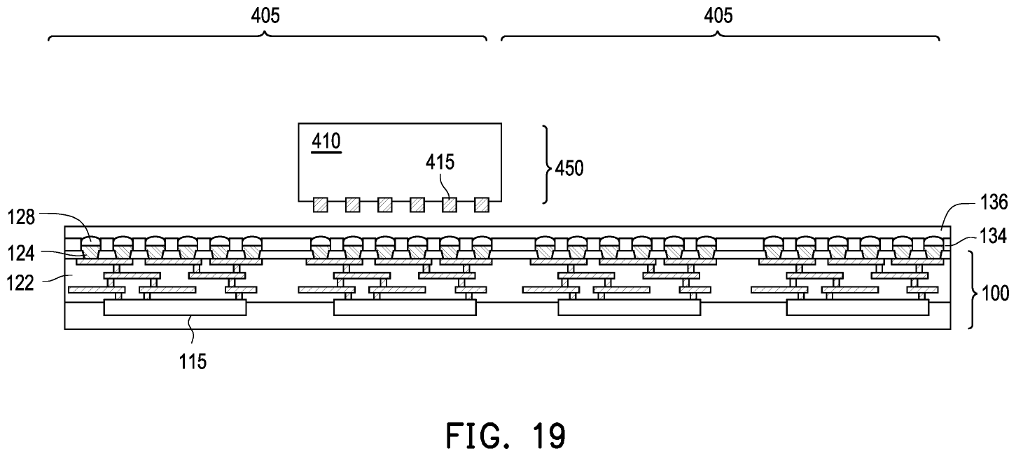

FIG. 19 illustrates a TCB process and baking process in accordance with other embodiments. Like elements have like reference numbers. In FIG. 19, rather than singulate the wafer 100 into the package components, package components 450 having metal pillars, like unto the package component 200 having metal pillars 215 are brought to the wafer 100, for example, by a pick and place process. Then the metal pillars 415 of the package components 450 can be pressed through the NCF 136 to contact the solder regions 128. Similar to that described above with respect to FIGS. 13A, 13B, 14A, and 14B the metal pillars 415 may or may not stab into the solder regions 128. Then, a TCB process and baking process, such as that described above may be performed, resulting in joints similar to those described and illustrated with respect to FIGS. 15A to 15F, except that the joint images are vertically flipped.

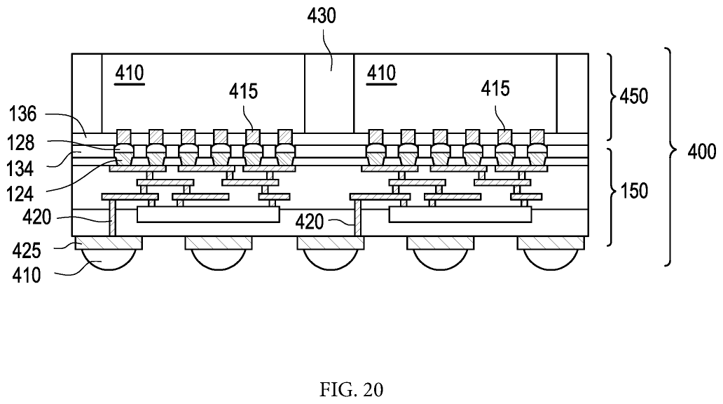

In FIG. 20, an encapsulant 430 may be deposited to surround the package components 450. The encapsulant 430 may be formed using processes and materials similar to the encapsulant 230. The encapsulant 430 may then by planarized and the package components 450 optionally thinned. The structure may then be singulated between package regions 405 (see FIG. 19) using a singulation process like unto the singulation process 205s, resulting in discrete package components 400.

Before or after singulation, conductive connectors 410 may be formed on contact pads 425, thereby coupling a through via 420 to an interconnect of the package component 150. The conductive connectors 410, contact pads 405, and through via 420 are like unto the conductive connectors 310, contact pads 305, and through via 320 and may be formed using similar processes and materials.

Embodiments advantageously provide an infill structure to capture solder materials within confines of openings of the infill structure so that the solder materials do not bridge from one connector to another connector. Embodiments advantageously provide the infill structure in a fine pitch bonded package, for example, below 10 μm. Embodiments also provide an underfill free design by utilizing a non-conductive film over the infill structure, metal pillars can penetrate through the non-conductive film so that each of the pillars is advantageously surrounded by the non-conductive film for further joint support. Because the metal pillars can stab into the solder regions prior to reflow, the resulting joints can include that the solder regions can surround and contact sidewalls of the metal pillars, forming a connection having less resistance.

One embodiment is a method including forming an underbump structure on a workpiece, the underbump structure electrically coupled to a metal feature embedded in the workpiece. The method also includes forming a solder bump on the underbump structure to form a solder structure. The method also includes depositing a first support layer over and laterally surrounding the solder structure. The method also includes planarizing the first support layer to level an upper surface of the solder structure with an upper surface of the first support layer. The method also includes depositing a non-conductive film over the first support layer and over the solder structure. The method also includes and singulating the workpiece to release a die.

In an embodiment, forming the solder bump on the underbump structure may include forming a plating mask surrounding the underbump structure, and plating the solder bump onto the underbump structure. In an embodiment, the method may include, after planarizing the first support layer, reflowing the solder bump. In an embodiment, the method may include aligning the die to a second workpiece, the second workpiece may include a metal pillar extending from a first surface thereof, pressing the die to the second workpiece to contact the metal pillar to the solder structure, and reflowing the solder bump. In an embodiment, the metal pillar penetrates into the solder structure prior to reflowing the solder bump. In an embodiment, during reflowing the solder bump, solder material of the solder bump flows into the non-conductive film. In an embodiment, an outer surface of the metal pillar contacts the solder structure, where the outer surface is rounded.

Another embodiment is a method including providing a first workpiece including a metal pillar protruding from an upper surface of the first workpiece. The method also includes aligning a eutectic connector of a die to the metal pillar, the die including the eutectic connector electrically coupled to a metal feature of the die, a first film laterally surrounding the eutectic connector, and a second film disposed on the first film and on the eutectic connector. The method also includes pressing the die to the first workpiece, the metal pillar penetrating the second film and contacting the eutectic connector. The method also includes reflowing the eutectic connector to electrically and physically couple the die to the first workpiece.

In an embodiment, following reflowing the eutectic connector, the second film contacts a surface of the first workpiece. In an embodiment, pressing the die to the first workpiece causes the metal pillar to penetrate into the eutectic connector. In an embodiment, reflowing the eutectic connector causes material of the eutectic connector to flow into the second film and laterally surround a portion of the metal pillar. In an embodiment, the second film may include an epoxy resin with filler and flux. In an embodiment, the metal pillar has a rounded tip. In an embodiment, a thickness of the second film is less than a height of the metal pillar. In an embodiment, the eutectic connector is disposed on a top metal feature of the die, where following reflowing the eutectic connector, the eutectic connector is confined within lateral extents of the top metal feature of the die. In an embodiment, prior to pressing the die to the first workpiece, the eutectic connector has a flat outer surface.

Another embodiment is a device including a first workpiece, the first workpiece may include a metal pillar extending vertically from an upper surface of the first workpiece. The device also includes a second workpiece, the second workpiece may include a metal pad along a lower surface of the second workpiece. The device also includes a eutectic connector extending between and coupling the metal pillar and the metal pad. The device also includes a first film abutting the lower surface of the second workpiece, the first film laterally encapsulating the metal pad and at least portion of the eutectic connector. The device also includes a second film abutting an upper surface of the first workpiece and a lower surface of the first film, the second film laterally encapsulating the metal pillar.

In an embodiment, the eutectic connector extends into the second film and surrounds an outer surface of the metal pillar. In an embodiment, the metal pillar has a rounded end embedded in the eutectic connector. In an embodiment, the metal pillar penetrates into the first film.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming an underbump structure on a workpiece, the underbump structure electrically coupled to a metal feature embedded in the workpiece;
forming a solder bump on the underbump structure to form a solder structure;
depositing a first support layer over and laterally surrounding the solder structure;
planarizing the first support layer to level an upper surface of the solder structure with an upper surface of the first support layer;
depositing a non-conductive film over the first support layer and over the solder structure; and
singulating the workpiece to release a die.

2. The method of claim 1, wherein forming the solder bump on the underbump structure comprises:
forming a plating mask surrounding the underbump structure; and
plating the solder bump onto the underbump structure.

3. The method of claim 1, further comprising:
after planarizing the first support layer, reflowing the solder bump.

4. The method of claim 1, further comprising:
aligning the die to a second workpiece, the second workpiece comprising a metal pillar extending from a first surface thereof;
pressing the die to the second workpiece to contact the metal pillar to the solder structure; and
reflowing the solder bump.

5. The method of claim 4, wherein the metal pillar penetrates into the solder structure prior to reflowing the solder bump.

6. The method of claim 4, wherein during reflowing the solder bump, solder material of the solder bump flows into the non-conductive film.

7. The method of claim 4, wherein an outer surface of the metal pillar contacts the solder structure, wherein the outer surface is rounded.

8. A method comprising:
providing a first workpiece including a metal pillar protruding from an upper surface of the first workpiece;
aligning a eutectic connector of a die to the metal pillar, the die including the eutectic connector electrically coupled to a metal feature of the die, a first film laterally surrounding the eutectic connector, and a second film disposed on the first film and on the eutectic connector;
pressing the die to the first workpiece, the metal pillar penetrating the second film and contacting the eutectic connector; and
reflowing the eutectic connector to electrically and physically couple the die to the first workpiece.

9. The method of claim 8, wherein following reflowing the eutectic connector, the second film contacts a surface of the first workpiece.

10. The method of claim 8, wherein pressing the die to the first workpiece causes the metal pillar to penetrate into the eutectic connector.

11. The method of claim 8, wherein reflowing the eutectic connector causes material of the eutectic connector to flow into the second film and laterally surround a portion of the metal pillar.

12. The method of claim 8, wherein the second film comprises an epoxy resin with filler and flux.

13. The method of claim 8, wherein the metal pillar has a rounded tip.

14. The method of claim 8, wherein a thickness of the second film is less than a height of the metal pillar.

15. The method of claim 8, wherein the eutectic connector is disposed on a top metal feature of the die, wherein following reflowing the eutectic connector, the eutectic connector is confined within lateral extents of the top metal feature of the die.

16. The method of claim 8, wherein prior to pressing the die to the first workpiece, the eutectic connector has a flat outer surface.

17. A device comprising:
a first workpiece, the first workpiece comprising a metal pillar extending vertically from an upper surface of the first workpiece;
a second workpiece, the second workpiece comprising a metal pad along a lower surface of the second workpiece;
a eutectic connector extending between and coupling the metal pillar and the metal pad;
a first film abutting the lower surface of the second workpiece, the first film laterally encapsulating the metal pad and at least portion of the eutectic connector; and
a second film abutting an upper surface of the first workpiece and a lower surface of the first film, the second film laterally encapsulating the metal pillar.

18. The device of claim 17, wherein the eutectic connector extends into the second film and surrounds an outer surface of the metal pillar.

19. The device of claim 17, wherein the metal pillar has a rounded end embedded in the eutectic connector.

20. The device of claim 17, wherein the metal pillar penetrates into the first film.
